(19) United States
(12) Patent Application Publication
(10) Pub. No.: US 2022/0013154 A1
(43) Pub. Date: Jan. 13, 2022

(54) Low Power Content Addressable Memory

(71) Applicant: Sudarshan Kumar, Fremont, CA (US)

(72) Inventor: Sudarshan Kumar, Fremont, CA (US)

(21) Appl. No.: 17/327,602

(22) Filed: May 21, 2021

Related U.S. Application Data
(63) Continuation-in-part of application No. 15/390,500, filed on Dec. 25, 2016, now Pat. No. 11,017,858.
(60) Provisional application No. 62/387,328, filed on Dec. 29, 2015.

(51) Int. Cl. G11C 7/22; G11C 7/10; G11C 15/04

(52) U.S. Cl. CPC G11C 7/222; G11C 15/04; G11C 7/1066; G11C 7/1093

(57) ABSTRACT

An integrated circuit might comprise an input flip-flop block clocked by a first clock having a first clock period, an output of the input flip-flop block for outputting data clocked by the first clock, a first logic block implementing a desired logic function, an input of the first logic block, coupled to the input flip-flop block, an output flip-flop block clocked by a second clock having a period equal to the first clock period and derived from a common source as the first clock, and an input of the output flip-flop block, coupled to an output of the first logic block. A first logic block delay can be at least the first clock period plus a specified delay excess and the second clock can be delayed by at least the specified delay excess. The first logic block might be a portion of a CAM block and/or a TCAM block.

### CROSS-REFERENCES TO PRIORITY AND RELATED APPLICATIONS

This application is a continuation-in-part of, and claims priority from, U.S. patent application Ser. No. 15/390,500 entitled “Low Power Content Addressable Memory” filed Dec. 25, 2016 (now issued as U.S. Pat. No. 11,017,858), which in turn claims the benefit of U.S. Provisional Patent Application No. 62/387,328, filed Dec. 29, 2015, entitled “Low Power Content Addressable Memory.” The entire disclosures of applications/patents recited above are hereby incorporated by reference, as if set forth in full in this document, for all purposes.

### FIELD

The present disclosure relates to clocked integrated circuits generally and more particularly to circuits for clocking flip-flop blocks in a CAM or TCAM memory.

### BACKGROUND

In every generation, the amount of memory needed by systems goes up. As a result, there is lots of memory in any system. Some memories are standalone memories while other memories are embedded in other devices. Out of these memories, some are content addressable memory (CAM), which is used for very fast table lookup. CAM is also called associative memory, where this type of memory is addressed by the data it holds. Another type of CAM is ternary CAM (TCAM). For each bit of data stored in TCAM, it also holds mask bit which, when set, generates/forces a match for that bit. TCAM requires twice the number of storage latches to store both data and its mask. In the case of CAM and TCAM, much power is consumed as all the searches are done in parallel. In networking, the TCAM sizes are in several megabits and hence power consumed by these TCAMs is a significant portion of power consumed in integrated circuits using these TCAMs.

Improvements of the power problem in CAM and TCAM without sacrificing speed or area are desirable.

### SUMMARY

An integrated circuit might comprise an input flip-flop block clocked by a first clock having a first clock period, an output of the input flip-flop block for outputting data clocked by the first clock, a first logic block implementing a desired logic function, an input of the first logic block, coupled to the output of the input flip-flop block, an output flip-flop block clocked by a second clock having a second clock period equal to the first clock period and the second clock derived from a common source as the first clock, and an input of the output flip-flop block, coupled to an output of the first logic block, wherein when a logic delay of the first logic block is at least the first clock period plus a specified delay excess, and wherein the second clock is delayed by at least the specified delay excess.

The first logic block might be a portion of a CAM block and/or a portion of a TCAM block. The specified delay excess might be more than the first clock period, such as up to 10% or more of the first clock period. The specified delay excess might be more than 50% of the first clock period.

This Summary is provided to introduce a selection of concepts in a simplified form that are further described below in the Detailed Description. This Summary is not intended to identify key features or essential features of the claimed subject matter, nor is it intended to limit the scope of the claimed subject matter. A more extensive presentation of features, details, utilities, and advantages of the surface computation method, as defined in the claims, is provided in the following written description of various embodiments of the disclosure and illustrated in the accompanying drawings.

### BRIEF DESCRIPTION OF THE DRAWINGS

Various embodiments in accordance with the present disclosure will be described with reference to the drawings, in which:

FIG. 1 shows a general row/column structure of a CAM or a TCAM of the prior art.

FIG. 2 is a block diagram of a CAM/TCAM memory row of the prior art.

FIG. 3 is a schematic diagram of a prior art XNOR gate used in a CAM/TCAM.

FIG. 4 is a block diagram of a bit cell of a modified TCAM, according to an embodiment.

FIG. 5 is a logic table as might be used in the bit cell of FIG. 4, according to an embodiment.

FIG. 6 illustrates a low-power implementation of an XNOR cell used in a modified TCAM, according to an embodiment.

FIG. 7 illustrates gate logic as might be present in the XNOR cell of FIG. 6, according to an embodiment.

FIG. 8 illustrates an example of a circuit that might be used for gates of FIG. 7, according to an embodiment.

FIG. 9 illustrates an example of an alternative circuit that might be used for gates of FIG. 7, according to an embodiment.

FIG. 10 illustrates is a block diagram of a row of CAM/TCAM, according to an embodiment.

FIG. 11 illustrates an example schematic of AND-ing logic, as might be used in the combining logic of FIG. 10, according to an embodiment.

FIG. 12 is block diagram of a TCAM array with input and output flip-flops, according to an embodiment.

FIG. 13 illustrates a clock waveform for a normal clocking scheme, according to an embodiment.

FIG. 14 illustrates a clock waveform for a novel clocking scheme, according to an embodiment.

FIG. 15 illustrates a buffering scheme using buffers, according to an embodiment.

FIG. 16 illustrates a buffering scheme using inverting logic, according to an embodiment.

### DETAILED DESCRIPTION

In the following disclosure, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

The following disclosure describes low-power CAMs and TCAMs. CAMs and TCAMs are well known and are described in textbooks and publications, so some details are avoided here for clarity.

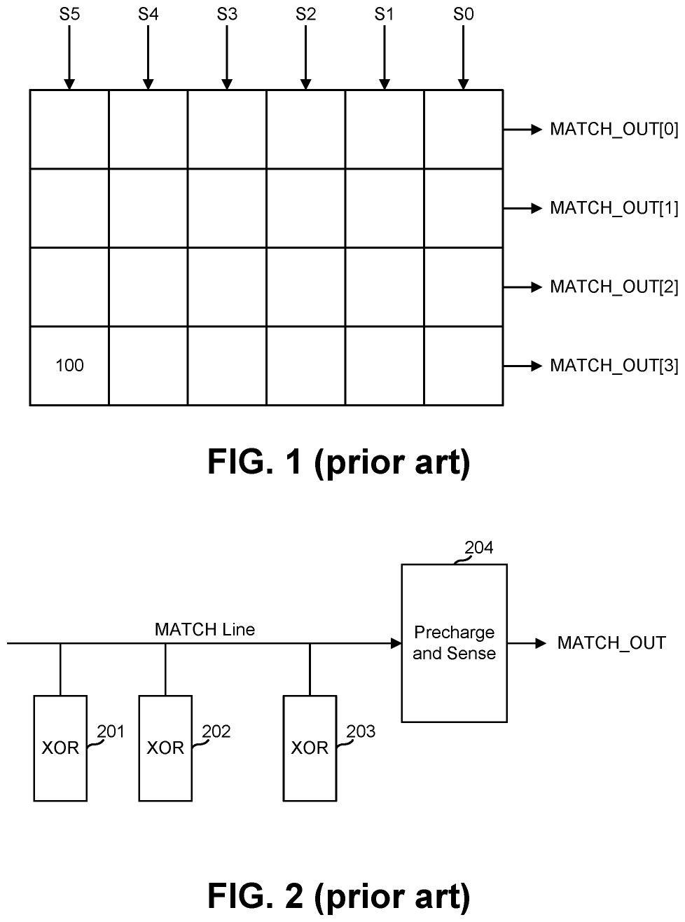

FIG. 1 is a simplified block diagram showing a row and column structure 100 of a conventional CAM/TCAM. Data to be searched are stored in rows. The column indicates a width of the stored data. The number of rows indicates the number of data items that are stored in the CAM/TCAM to be searched. In this example, six bits of search data (S5 through S0) are used to search this example CAM/TCAM. If a match is found in row i, the corresponding MATCH_OUT[i] line is turned on.

FIG. 2 is a simplified block diagram of a row of typical CAM/TCAM match logic. For speed and area reasons, domino (precharged and discharge) circuits can be used for implementation. Search data is the data that is being searched in the CAM/TCAM. Each bit of search data is compared with corresponding bits for each row bit cell using XOR cells 201, 202, . . . , 203, containing only pulldown XOR logic. The output of each XOR cell is connected to a MATCH line, which is precharged in a precharge phase of a clock. In an evaluation phase of the clock, each XOR with a mismatch will discharge MATCH lines. Since a match typically happens in only one row of the CAM/TCAM, only one matching row will not have its MATCH line discharged. For all other rows, the MATCH lines are discharged. As a result, with the MATCH lines in every row precharging and discharging every clock cycle, there is a huge amount of power consumption.

The MATCH line is highly loaded, as all the XOR cells in that row connected to the MATCH line. As a result, the MATCH lines transition very slowly and adds to a CAM/TCAM lookup delay. To speed up the lookup, a sense amplifier 204 is used to detect a value of the MATCH line and the output of the sense amplifier 204 is the MATCH_OUT line. In addition to a sense amplifier, many other techniques are used to improve speed as well as reduce power and area. Having precharge discharge circuits for finding matches, a domino CAM/TCAM's power consumption is very high. One way to reduce power is to use static gates for comparison and a match operation where switching activities on nodes are much lower as the nodes need not be precharged and discharged every cycle.

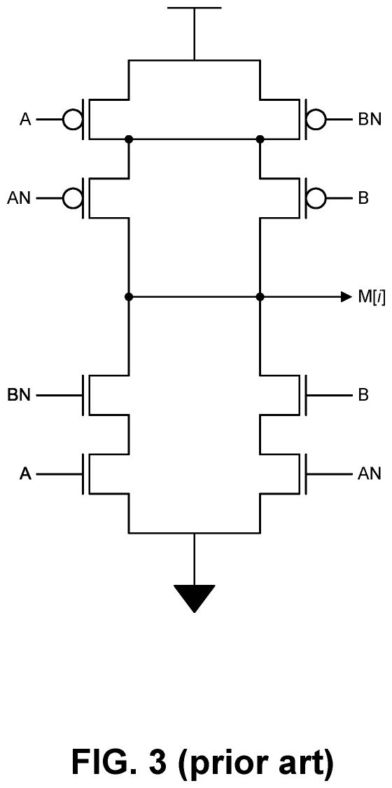

FIG. 3 is a schematic diagram of a prior art XNOR gate used in a CAM/TCAM. For low-power static implementations, typically static XNOR gates as shown in FIG. 3 are used. It is to be noted that a static gate can be used as an XOR gate by switching inputs. Since the gates are connected such that they provide the XNOR function, they are sometimes called XNOR gates. The output of these static XNOR gates for a whole row are combined together to generate a match result for that row. Done appropriately, this implementation saves power but adds a huge delay and area penalty.

The MATCH line that was a wired OR gate in the prior art domino implementation of FIG. 2 can be made using several stages of logic. The XNOR gate in FIG. 3 is full CMOS, hence it has eight CMOS transistors as compared to that of the prior art in FIG. 2, which has pulldown XNOR logic made of four NMOS (n-channel metal-oxide semiconductor) transistors. Using full CMOS XNOR logic combined with multistage combining logic increases the area used and increases delays. Embodiments described herein can be used to solve the area issue and the delay issue by using an alternative XNOR implementation and efficient implementation of the combining logic to generate match signals.

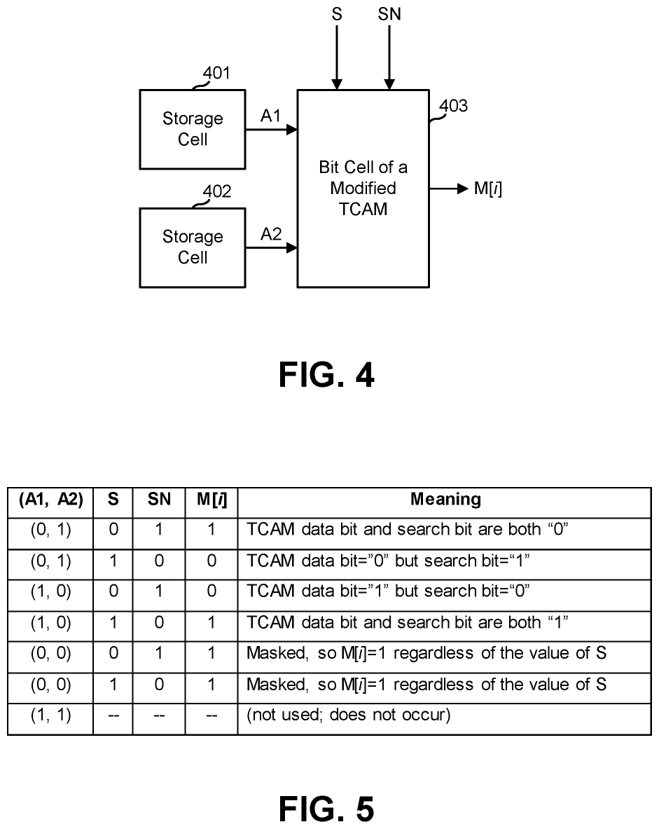

FIG. 4 is a block diagram of a bit cell of a modified TCAM, according to an embodiment. Herein, most of the examples refer to TCAM rather than CAM as the CAM function is a subset of the TCAM function. FIG. 4 shows one bit of a TCAM. Two storage cells 401 and 402 are used to store a data bit and a mask bit. Cell 403 in FIG. 4 implements a compare function (XOR or XNOR) with a mask function.

FIG. 5 is a logic table as might be used in the bit cell of FIG. 4, according to an embodiment. There are different ways to store these two bits into storage cells 401 and 402. An advantage of encoded bits is that the XOR/XNOR logic with a mask function is easy to implement with fewer transistors.

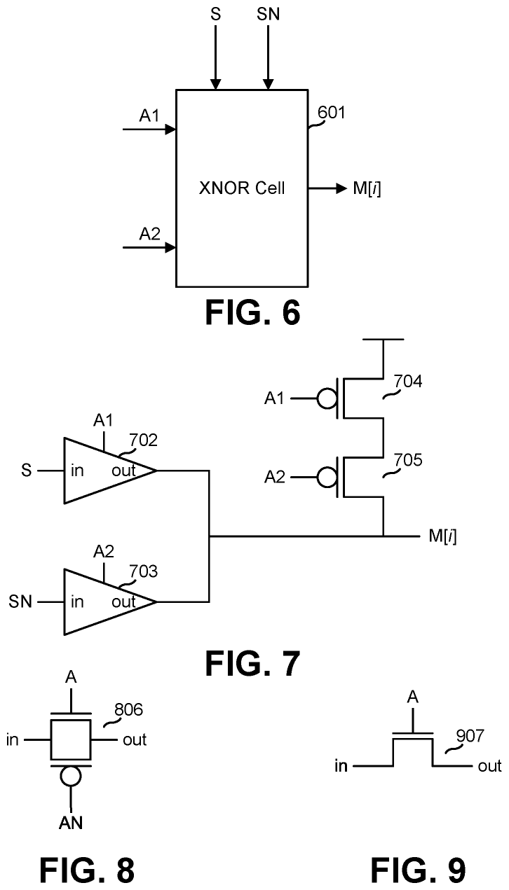

FIG. 6 illustrates a low-power implementation of an XNOR cell 601 used in a modified TCAM, according to an embodiment. XNOR cell 601 in FIG. 4 can function the same as XNOR cell 403 in FIG. 4.

FIG. 7 illustrates gate logic as might be present in the XNOR cell of FIG. 6, according to an embodiment. XNOR cell 601 of FIG. 6 can be implemented as in FIG. 7 as two tristate gates 702 and 703 and masking logic comprising two PMOS (p-channel metal-oxide semiconductor) transistors 704 and 705. When a mask for that TCAM cell is set, in the encoded scheme, both A1 and A2 have a “0” value as per the encoding table of FIG. 5. As a result, tristate gates 702 and 703 are off and PMOS transistors 704 and 705 are on, which forces M[i] to high with logical value of “1.”

It will be appreciated by one skilled in the art that by changing the encoding scheme and the switching input to a tristate gate, the masking logic can be implemented using two NMOS transistors that will force the output low when masking. In this case of an alternative encoding scheme, the output is active low and is the inverse of output M[i] in FIG. 6.

FIG. 8 illustrates an example of a circuit that might be used for gates of FIG. 7, according to an embodiment. In order to reduce area, power and delay, tristate gate 702 and 703 might each be implemented as passgates such as passgate 806 in FIG. 8, comprising PMOS and NMOS transistors. In FIG. 8, the AN signal is the inverse of the A signal, which is readily available from the storage cell and hence need not be generated again locally using an inverter.

Using passgates, XNOR cell 601 of FIG. 6 can be implemented using six transistors as compared to eight transistors in the circuit of FIG. 3. The power consumption of this XNOR cell 601 is very low and the delay of the passgate is low. Passgate 806 need not have both PMOS and NMOS transistors. It can be made with only one transistor.

FIG. 9 illustrates an example of an alternative circuit that might be used for passgates for those tristate gates 702 and 703 of FIG. 7, according to an embodiment. In one implementation, it can be made of only NMOS transistors, such as transistor 907 shown in FIG. 9. Even though output M[i] may not reach the full rail high voltage, the rest of the combining logic can work at a lower voltage level, thereby reducing power further. Even search data S and SN can have a lower high voltage so that there is less power consumption. By using only one transistor 907 as a passgate, the total number of transistors to implement XNOR cell 601 of FIG. 6 is four, which is same number of transistors for the XOR used in a domino implementation.

Although a TCAM can implement the CAM function, the CAM function requires fewer transistors to implement, as it does not have to deal with masking. It requires only one storage cell to store data, as it need not store a masking bit. It also does not need masking logic implemented using transistors 704 and 705 as in FIG. 7. The rest of the logic and implementations can be the same as for TCAM. There is match if all the bits in a row match. That means that the bit match signal M[i] is high in all the TCAM cells in that row.

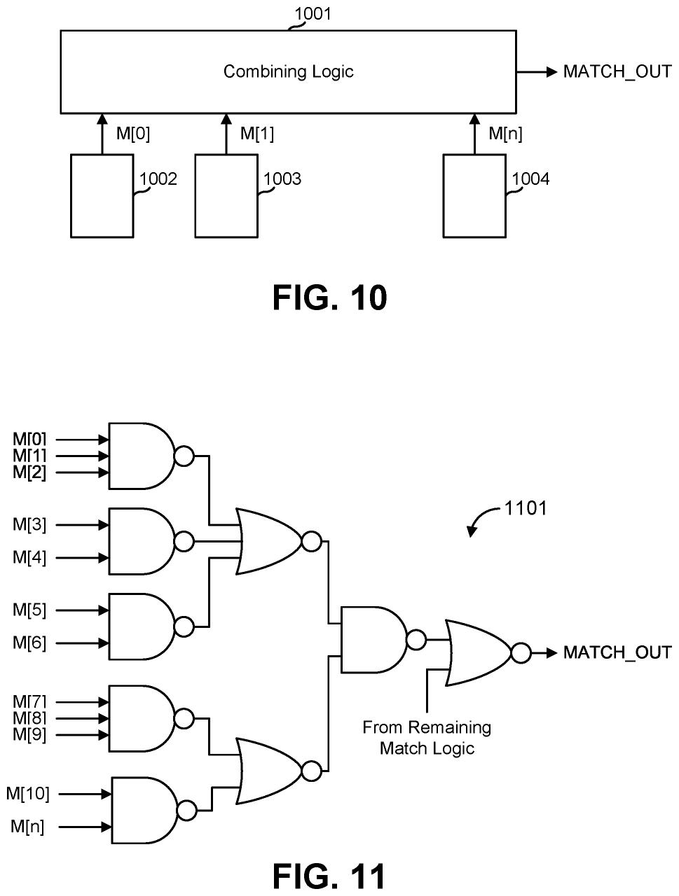

FIG. 10 illustrates is a block diagram of a row of CAM/TCAM, according to an embodiment. To get match signals, all M[i] outputs of the TCAM cells can be combined using AND-ing or NAND-ing logic to detect an “all high on M[i]” signal of each of the TCAM cells as shown in FIG. 10.

In FIG. 10, all the M[i] outputs, from M[0] to M[n] of individual TCAM cells 1002, 1003, . . . , 1004, are fed into combining logic 1001 to generate a MATCH_OUT output of that row. Combining logic 1001 may use other inputs, such as a row valid bit (not shown).

FIG. 11 illustrates an example schematic of AND-ing logic, as might be used in the combining logic of FIG. 10, according to an embodiment. While there are various ways to implement this NAND-ing or AND-ing operation, one preferred implementation is as shown in FIG. 11. There, alternate rows of NAND gates and NOR gates are shown for combining all M[i] outputs of each TCAM cell of a row to generate the MATCH_OUT output. A goal here is to combine all M[i] outputs using fewer levels of logic, to reduce the delay in the combining logic. It is important to notice that switching activity goes down with the number of levels. Also, an output of a three-input NAND gate has less switching activity as compared to a two-input NAND gate. In order to reduce power, the first level NAND gates should have more inputs, if possible.

Note that if the M[i] signal TCAM bit is implemented with low logic, then NOR-ing or OR-ing functions might be used as the combining logic to detect a match. In FIG. 11, the first row has NOR gates followed by alternating rows of NAND and NOR gates.

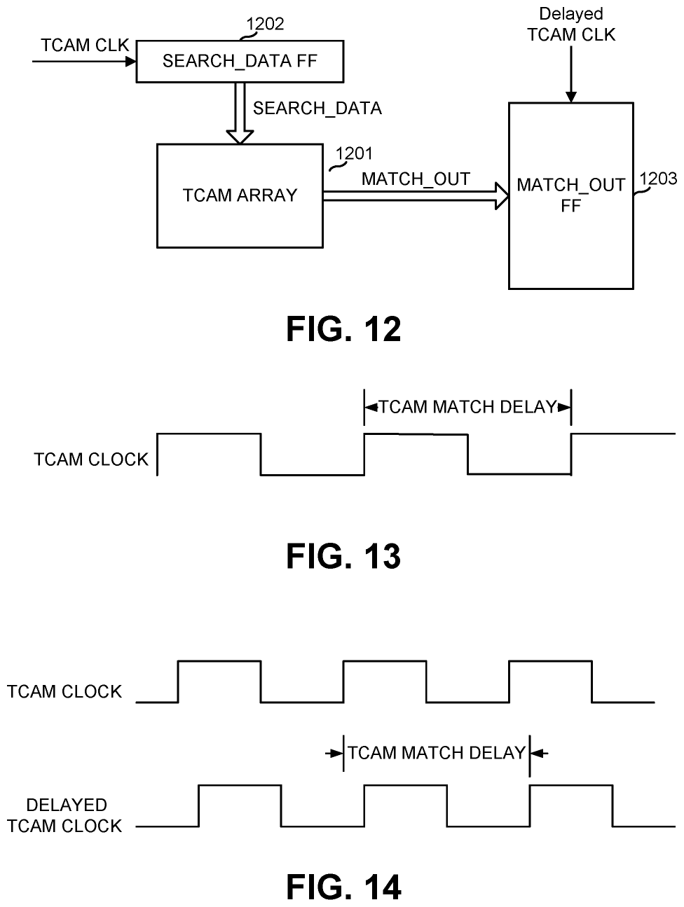

FIG. 12 is block diagram of a TCAM array with input and output flip-flops, according to an embodiment. Typically, TCAM match array evaluation uses many logic gates as well as having RC delays and so may not work at the desired frequency. To allow for faster clock frequencies, TCAM blocks can borrow time from a next block in pipeline. The next block is usually a priority encoder, which is a lot faster. This is accomplished by delaying a clock of output transitions of a TCAM such that TCAM match logic has more than a clock period to evaluate.

FIG. 12 shows a TCAM array 1201 with an input flip-flop block 1202 driving SEARCH_DATA which goes as the input to TCAM array 1201. The output MATCH_OUT gets flopped by an output flip-flop block 1203. Conventionally, both input the input flip-flop block 1202 and the output flip-flop block 1203 might be clocked by clocks having the same period and typically are derived from the same source clock. In that case, the total delay is the sum of the output delay (clk to output) of the input flip-flop block 1202, a TCAM array delay and a setup delay of the output flip-flop block 1203, and the total delay must be less than a clock period. If this condition is not satisfied, then TCAM will not produce the correct result and the operating clock frequency must be decreased.

FIG. 13 illustrates a clock waveform for a normal clocking scheme, according to an embodiment. As shown there, the TCAM clock frequency is limited by the TCAM match delay.

FIG. 14 illustrates a clock waveform for a novel clocking scheme, according to an embodiment. As shown in FIG. 14, the clock of the output flip-flop block 1203 of FIG. 12 is receiving these match signals is delayed considerably so that the match evaluation has more time than a clock period and hence the TCAM can work at a higher clock frequency and is not limited by the TCAM array delay, which is more than a clock period. This innovation can be used in other types of designs, such as memory and logic blocks, data path and control to get these blocks to operate at higher frequencies and is not limited by inherent delays of these blocks.

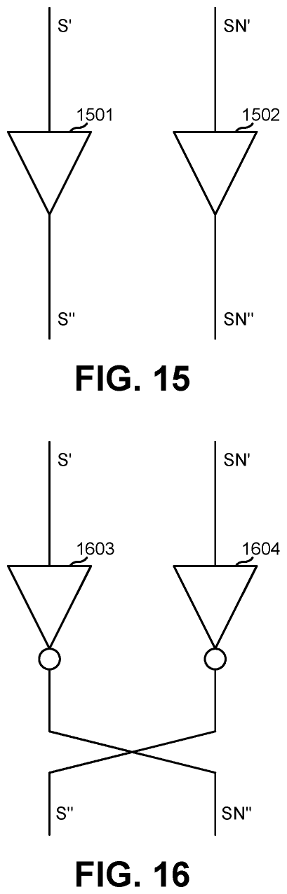

Search data goes through each row of the TCAM and hence they have long lines with large RC delays. In order to reduce the RC delay, search data lines are broken into segments as in, for example, FIG. 15. FIG. 15 illustrates a buffering scheme using buffers, according to an embodiment. In FIG. 15, S is broken in two segments, shown as S′ and 5″, and the S″ segment is driven by a buffer 1501. This reduces the RC delay on search line S. There can be multiple stages of buffering. Similarly, a complement, SN, of search data S is also buffered by buffer 1502 (buffering SN′ to SN″) which can reduce the RC delay. Typically, a buffer might comprise at least two inverting gates. This has more delay as compared to the scheme of the example shown in FIG. 16, where only one inverting stage 1603 (between S′ and SN″) and inverting stage 1604 (between SN′ and 5″) are used to buffer. Hence, the buffering scheme in FIG. 16 is faster than the buffering scheme in FIG. 15.

An issue with implementation with static gates is power modeling of the TCAM/CAM. In the case of a domino implementation, all internal power consumption is assigned to a clock as all nodes precharge and discharge with the clock and consume about the same amount of power. In the case of static implementation, power consumption depends on activity of internal nodes of search lines, match logic of the TCAM /CAM cell and the combining logic of the TCAM/CAM row. In an embodiment, power is modeled as a function of switching activity on search inputs and the flopped version of search inputs that goes to all the TCAM cells. This way power gets modeled correctly. This concept can be used in other types of static memory and static logic blocks as well.

The use of examples, or exemplary language (e.g., “such as”) provided herein, is intended merely to better illuminate embodiments and does not pose a limitation on the scope of the invention unless otherwise claimed. No language in the specification should be construed as indicating any non-claimed element as essential to the practice of the invention.

In the foregoing specification, embodiments have been described with reference to numerous specific details that may vary from implementation to implementation. The specification and drawings are, accordingly, to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction.

Further embodiments can be envisioned to one of ordinary skill in the art after reading this disclosure. In other embodiments, combinations or sub-combinations of the subject matter disclosed herein can be advantageously made. All references, including publications, patent applications, and patents, cited herein are hereby incorporated by reference to the same extent as if each reference were individually and specifically indicated to be incorporated by reference and were set forth in its entirety herein.

What is claimed is:

1. An integrated circuit comprising:
an input flip-flop block clocked by a first clock having a first clock period;
an output of the input flip-flop block for outputting data clocked by the first clock;
a first logic block implementing a desired logic function;
an input of the first logic block, coupled to the output of the input flip-flop block;
an output flip-flop block clocked by a second clock having a second clock period equal to the first clock period and the second clock derived from a common source as the first clock; and
an input of the output flip-flop block, coupled to an output of the first logic block,
wherein when a logic delay of the first logic block is at least the first clock period plus a specified delay excess, and wherein the second clock is delayed by at least the specified delay excess.

2. The integrated circuit of claim 1, wherein the first logic block is a portion of a CAM block or a portion of a TCAM block.

3. The integrated circuit of claim 1, wherein the specified delay excess is more than 10% of the first clock period.

4. The integrated circuit of claim 1, wherein the specified delay excess is more than 50% of the first clock period.
